(19) United States
(12) Patent Application Publication
(10) Pub. No.: US 2025/0323023 A1
(43) Pub. Date: Oct. 16, 2025

(54) Heated Lid Ring for Chamber Wall Temperature Control

(71) Applicant: Applied Materials, Inc., Santa Clara, CA (US)

(72) Inventors: Imad YOUSIF, San Jose, CA (US); John Anthony O'MALLEY, III, Campbell, CA (US); Jeffrey LUDWIG, San Jose, CA (US); Santosh NESARKAR, Bangalore (IN)

(21) Appl. No.: 18/637,359

(22) Filed: Apr. 16, 2024

(51) Int. Cl. H01J 37/32

(52) U.S. Cl. CPC H01J 37/32522; H01J 37/32513

(57) ABSTRACT

Embodiments of lid assemblies for a process chamber are provided herein. In some embodiments, a lid assembly for a process chamber includes: a dielectric lid plate coupled to a first heater having one or more resistive heating elements disposed therein that are configured to heat the dielectric lid plate; a lid ring disposed about the dielectric lid plate and configured to hold the dielectric lid plate, wherein the lid ring includes a first heater ring disposed at an inner end of the lid ring and about the dielectric lid plate that includes a second heater comprising one or more resistive heating elements and wherein a radially inner surface of the first heater ring is spaced from an opposing radially outer surface of the dielectric lid plate so that the first heater ring is not in direct contact with the dielectric lid plate.

### FIELD

Embodiments of the present disclosure generally relate to substrate processing equipment.

### BACKGROUND

Inductively coupled plasma (ICP) process reactors generally form plasmas by inducing current in a process gas disposed within the process chamber via one or more inductive coils disposed outside of the process chamber. The inductive coils may be disposed externally and separated electrically from the chamber by, for example, a dielectric lid assembly. When radio frequency (RF) current is fed to the inductive coils via an RF feed structure from an RF power source, an inductively coupled plasma can be formed inside the chamber through a lid assembly of the process chamber via an electric field generated by the inductive coils.

The plasma formed in the chamber body may be used to perform a suitable process on a substrate, for example, an etch process, a deposition process, a thermal process, or the like. A flow valve may be coupled to the chamber body and facilitate exhausting the byproducts of the process. Temperature uniformity of the chamber body, the lid assembly, and the flow valve improves process uniformity and reduces unwanted deposits on inner surfaces of chamber components. Conventionally, heat exchangers that circulate a fluid through channels in the chamber body are used for temperature control of the chamber body. However, such components are costly, leave a large physical footprint, and are prone to leaks that lead to increased process chamber downtime for maintenance.

Accordingly, the inventors have devised an improved lid assembly and improved process chamber to better control chamber body temperature.

### SUMMARY

Embodiments of lid assemblies for a process chamber are provided herein. In some embodiments, a lid assembly for a process chamber includes: a dielectric lid plate coupled to a first heater having one or more resistive heating elements disposed therein that are configured to heat the dielectric lid plate; a lid ring disposed about the dielectric lid plate and configured to hold the dielectric lid plate, wherein the lid ring includes a first heater ring disposed at an inner end of the lid ring and about the dielectric lid plate that includes a second heater comprising one or more resistive heating elements and wherein a radially inner surface of the first heater ring is spaced from an opposing radially outer surface of the dielectric lid plate so that the first heater ring is not in direct contact with the dielectric lid plate.

In some embodiments, a process chamber includes: a chamber body having an interior volume therein defined by sidewalls and a lid assembly disposed atop the sidewalls; an upper liner disposed in the interior volume; wherein the lid assembly comprises: a dielectric lid plate coupled to a first heater having one or more resistive heating elements disposed therein that are configured to heat the dielectric lid plate; and a lid ring disposed about the dielectric lid plate and configured to hold the dielectric lid plate, wherein the lid ring includes a first heater ring disposed at an inner end of the lid ring and about the dielectric lid plate that includes a second heater comprising one or more resistive heating elements, wherein the first heater ring is spaced from the dielectric lid plate and not in direct contact with the dielectric lid plate, and wherein the first heater ring is in physical contact with the upper liner; a flow valve body coupled to a lower end of the chamber body; and a second heater ring disposed between the flow valve body and the chamber body and having a third heater comprising one or more resistive heating elements disposed therein and configured to heat the flow valve body.

In some embodiments, a process chamber includes: a chamber body having an interior volume therein defined by sidewalls and a lid assembly disposed atop the sidewalls; an upper liner disposed in the interior volume; wherein the lid assembly comprises: a dielectric lid plate coupled to a first heater having one or more resistive heating elements disposed therein that are configured to heat the dielectric lid plate; and a lid ring disposed about the dielectric lid plate and configured to clamp the dielectric lid plate against the upper liner, wherein the lid ring includes a first heater ring disposed at an inner end of the lid ring and about the dielectric lid plate that includes a second heater comprising one or more resistive heating elements, wherein the first heater ring is spaced from the dielectric lid plate and not in direct contact with the dielectric lid plate, and wherein the first heater ring is in physical contact with the upper liner; a flow valve body coupled to a lower end of the chamber body; a second heater ring disposed between the flow valve body and the chamber body and having a third heater disposed therein comprising one or more resistive heating elements disposed therein and configured to heat the flow valve body; and a plasma source coupled to a top of the lid assembly.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a process chamber in accordance with at least some embodiments of the present disclosure.

FIG. 2 depicts a top isometric view of a lid assembly in accordance with at least some embodiments of the present disclosure.

FIG. 3 depicts a cross-sectional view of an upper portion of a process chamber in accordance with at least some embodiments of the present disclosure.

FIG. 4 depicts an isometric view of a lid ring in accordance with at least some embodiments of the present disclosure.

FIG. 5 depicts a cross-sectional view of a lower portion of the process chamber in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of process chambers having enhance temperature control of chamber components such as chamber bodies are provided herein. The enhanced temperature control is at least partially provided by the lid assemblies coupled to an upper portion of the chamber bodies disclosed herein. The lid assemblies generally include a lid ring having a heater that comprises one or more resistive heating elements that are configured to heat an upper liner of a process chamber and a chamber body of the process chamber via the lid ring. The inventors have observed that heating of the chamber body of the process chamber via resistive heating elements advantageously provides temperature control of the chamber body with a reduced cost and a smaller physical footprint as compared to conventional methods.

The lid assemblies provided herein are also not prone to leaks that lead to increased process chamber downtime for maintenance. The enhanced temperature control of the chamber bodies may further be provided by a heater ring having resistive heating elements that is coupled to a lower portion of the chamber bodies. The enhanced temperature control of chamber components advantageously improves process uniformity and decreases unwanted deposition build up on surface of chamber components.

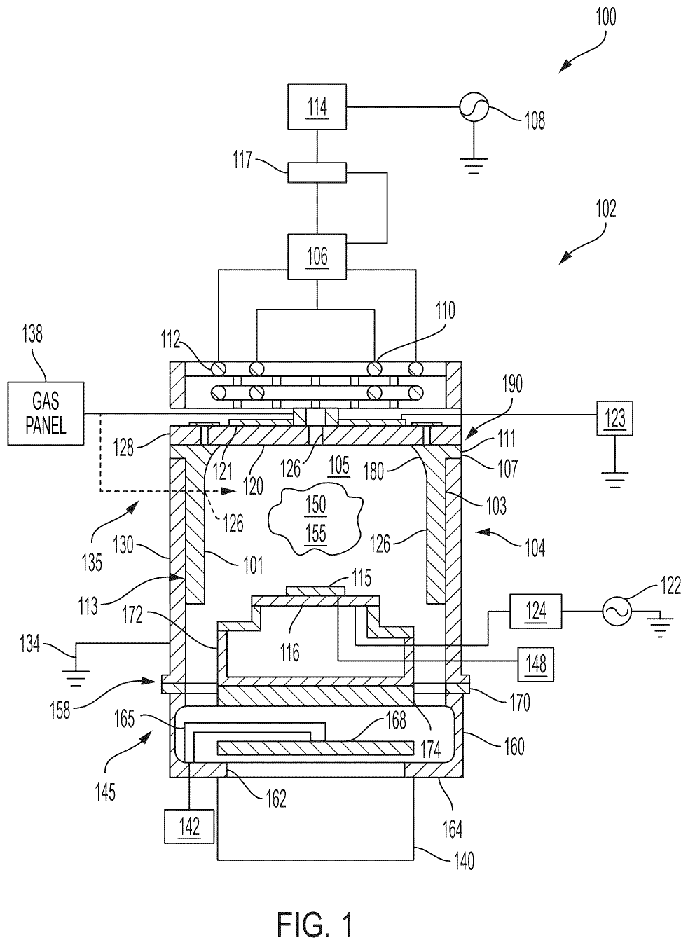

FIG. 1 depicts a schematic side view of a process chamber 100 in accordance with at least some embodiments of the present disclosure. The process chamber 100 may be an etch chamber having a lid assembly 190. The process chamber 100 may be utilized alone or as a processing module of an integrated semiconductor substrate processing system, or a cluster tool. Although FIG. 1 illustratively depicts an etch chamber, the lid assembly 190 may beneficially be utilized in other types of plasma process chambers, including chemical vapor deposition chambers, physical vapor deposition chambers, implantation chambers, nitriding chambers, plasma annealing chambers, plasma treatment chambers, and ashing chambers, among others.

The process chamber 100 generally includes a chamber body 104 having sidewalls 130 and the lid assembly 190 disposed atop the sidewalls 130 to define an interior volume 105 of the process chamber 100. The process chamber 100 includes an upper portion 135 and a lower portion 145. A substrate support 116 having a substrate 115 disposed thereon is disposed within the interior volume 105. A plasma source 102 comprising an inductively coupled plasma apparatus is disposed atop the lid assembly 190 and is configured to inductively couple RF power to the interior volume 105 through the lid assembly 190.

The sidewalls 130 are typically coupled to an electrical ground 134. The lid assembly 190 includes a dielectric lid plate 120 facing the interior volume 105 of the process chamber 100. In some embodiments, the substrate support 116 may be configured as a cathode coupled through a matching network 124 to a biasing power source 122. The biasing power source 122 may be a source that is capable of producing either continuous or pulsed power. In other embodiments, the biasing power source 122 may be a DC or pulsed DC source. In some embodiments, the biasing power source 122 may be capable of providing multiple frequencies. The temperature of the substrate 115 may be controlled by stabilizing a temperature of the substrate support 116. In some embodiments, helium gas from a gas source 148 may be provided via a gas conduit 149 to channels defined between the backside of the substrate 115. The helium gas is used to facilitate heat transfer between the substrate support 116 and the substrate 115. During processing, the substrate support 116 may be heated by a resistive heater (not shown) within the substrate support to a steady state temperature and the helium gas may facilitate uniform heating of the substrate 115. Using such thermal control, the substrate 115 may illustratively be maintained at a temperature of between 0 and 500 degrees Celsius.

The lid assembly 190 may include a lid ring 128 disposed about the dielectric lid plate 120. The lid ring 128 may be configured to clamp the dielectric lid plate 120 against the upper liner, A first heater 121 is coupled to the dielectric lid plate 120 to heat the dielectric lid plate 120 to control a temperature in the interior volume 105. The first heater 121 includes one or more resistive heating elements that are coupled to a power supply 123, such as an AC power supply, configured to provide sufficient energy to control the temperature of the dielectric lid plate 120 to be between about 50 to about 100 degrees Celsius. The first heater 121 may comprise the resistive heater elements encapsulated in a metallic material, such as aluminum for example, to shield the resistive heater elements from the RF power. The encapsulated heater elements form the first heater 121 that is adhered, clamped, or otherwise held to the exterior surface of the dielectric lid plate 120. The first heater 121 is generally disposed between the first and second coils 110, 112 and the dielectric lid plate 120.

In some embodiments, the plasma source 102 includes a plurality of inductively coupled plasma (ICP) coils, such as the first coil 110 and the second coil 112. The first coil 110 and the second coil 112 may be disposed in a vertical or flat (horizontal) orientation. Although only two coils are shown in FIG. 1, embodiments of the present disclosure may include one or more ICP coils with and without phase control between the coils' currents. The relative position, ratio of diameters of each coil, and/or the number of turns in each coil can each be adjusted to control, for example, the profile or density of the plasma being formed via controlling the inductance on each coil. In some embodiments, each of the first and second coils 110, 112 is coupled through a matching network 114 via an RF feed structure 106, to an RF power supply 108. In some embodiments, a power divider 117, such as a dividing capacitor, may be provided between the RF feed structure 106 and the RF power supply 108 to control the relative quantity of RF power provided to the respective first and second coils 110, 112.

In some embodiments, the process chamber 100 may comprise an upper liner 101 disposed within the interior volume 105 at an upper portion 135 of the chamber body 104 to manage temperature and/or control plasma distribution in the process chamber 100. The upper liner 101 may generally comprise an upper end 111 adjacent the lid assembly 190 and a second end 113 extending below a support surface of the substrate support 116. The upper liner 101 may comprise a tubular body 103 and an upper flange 107 extending radially outward of the tubular body 103. The upper flange 107 may rest on the sidewalls 130 of the chamber body 104. The upper liner 101 is generally in contact with the sidewalls 130 to facilitate heat transfer therebetween. The upper liner 101 generally has no heater channels or coolant channels disposed therein. In some embodiments, an upper interior surface 180 of the upper liner 101 is curved.

The lower portion 145 of the process chamber includes a flow valve body 160 that is coupled to a lower end 158 of the chamber body 104. The flow valve body 160 is configured to aid in directing exhaust gas out from the interior volume 105. A top plate of the flow valve body 160 may include port openings 174 aligned with port openings 172 of the chamber body 104. The flow valve body 160 is disposed between the chamber body 104 and a pump 140 coupled to the flow valve body 160. In some embodiments, the pump 140 is disposed vertically below the flow valve body 160 and vertically below the chamber body 104. The pump 140 may be a turbopump. The flow valve body 160 includes a port opening 162 on a bottom plate 164 of the flow valve body 160. A poppet 168 is disposed in an interior volume of the flow valve body 160 and configured to selectively open or close the port opening 162 via vertical movement of the poppet 168. In some embodiments, the poppet 168 is coupled to an arm 165 that can be selectively raised or lowered via an actuator 142.

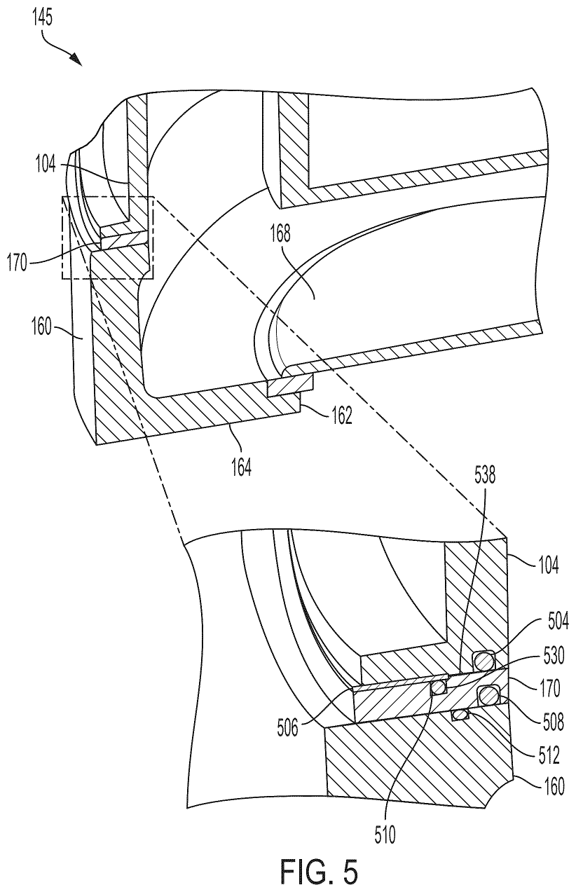

In some embodiments, a second heater ring 170 (described in more detail below in FIG. 5) is disposed between the flow valve body 160 and the chamber body 104 and configured to advantageously heat the flow valve body 160 and the chamber body 104. The second heater ring 170 includes one or more resistive heating elements. The second heater ring 170 may advantageously provide temperature control of the chamber body 104 to improve process uniformity and reduce unwanted deposits.

During operation, the substrate 115 (such as a semiconductor wafer or other substrate suitable for plasma processing) may be placed on the substrate support 116 and process gases may be supplied from a gas panel 138 through one or more gas inlets 126 to form a gaseous mixture 150 within the interior volume 105. In some embodiments, the one or more gas inlets 126 are in the lid assembly 190. In some embodiments, the one or more gas inlets 126 are through the upper liner 101. The gaseous mixture 150 may be ignited into a plasma 155 in the interior volume 105 by applying power from the RF power supply 108 to the first and second coils 110, 112.

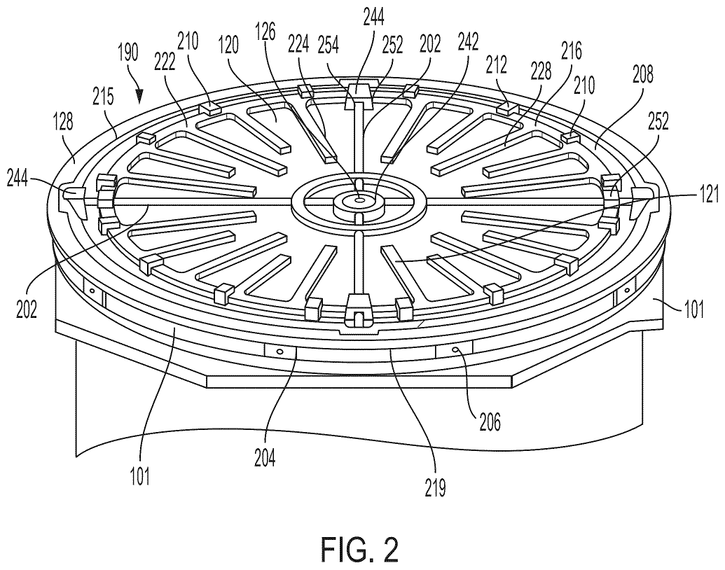

FIG. 2 depicts a top isometric view of a lid assembly 190 in accordance with at least some embodiments of the present disclosure. The lid assembly 190 generally comprises the lid ring 128 disposed about the dielectric lid plate 120. The lid ring 128 may be coupled to the upper liner 101. For example, the lid ring 128 may include a plurality of mounting brackets 204 extending from a lower surface 219 of the lid ring 128. A plurality of fasteners 206 may be used to fasten the lid ring 128 to the upper liner 101 via the plurality of mounting brackets 204.

The first heater 121 may be disposed atop the dielectric lid plate 120 and configured to heat the dielectric lid plate 120. The inventors have observed that although the lid assembly 190 may advantageously shield the plurality of resistive heating elements of the first heater 121 from the RF power, the lid assembly 190 also acts as a shield to the RF between the ICP coils (e.g., 110, 112) and the process chamber 100 which may affect power coupling of the plasma source 102 to the process chamber 100. As such, a shape of the first heater 121 may be used to control the sputtering rate through capacitive power coupling of the plasma source 102.

In some embodiments, the first heater 121 comprises an annular body 222 and a plurality of fingers 224 extending radially inward from the annular body 222. In some embodiments, at least one of the annular body 222 or the plurality of fingers 224 includes one or more resistive heating elements disposed therein. For example, the annular body 222 and the plurality of fingers 224 may comprise one or more resistive heating elements embedded in an electrical insulator. In some embodiments, the plurality of fingers 224 may be different lengths depending on the amount of surface area coverage is desired. For example, in some embodiments, as shown in FIG. 2, the plurality of fingers 224 alternate between shorter fingers and longer fingers. In other embodiments, the plurality of fingers 224 may be all the same length or have more than just two different lengths. The width of the plurality of fingers 224 may also be adjusted based on the amount of shield coverage of the lid is sought.

In some embodiments, an upper surface of the first heater 121 may include an RF shield 216 that advantageously protects the one or more resistive heating elements disposed in the first heater 121 from the magnetic and electrical field lines generated by the first coil 110 and the second coil 112. In some embodiments, a lower surface of the first heater 121 may include a conductive layer 228 to provide additional protection against RF and to promote heat transfer from the first heater 121 to the dielectric lid plate 120. In some embodiments, the one or more resistive heating elements of the first heater 121 are sandwiched between the RF shield 216 and the conductive layer 228.

The lid ring 128 may be configured to hold the dielectric lid plate 120 in a suitable manner. For example, in some embodiments, the lid ring 128 includes a plurality of clamps 210 coupled to an upper surface 208 of the lid ring 128. Each of the plurality of clamps 210 may include an upper lip 212 that extends radially inward from the lid ring 128 and over the dielectric lid plate 120 to restrict the dielectric lid plate 120 from at least one of horizontal or vertical movement. In some embodiments, the plurality of clamps 210 are arranged at regular intervals. In some embodiments, the plurality of clamps 210 are rotatably coupled to the lid ring 128 so that the upper lip 212 of each clamp can be rotated outward and not over the dielectric lid plate 120, allowing the dielectric lid plate 120 to be placed within a central opening 250 of the lid ring 128. The plurality of clamps 210 can be rotated inwards over the dielectric lid plate 120 to hold the dielectric lid plate 120 with respect to the lid ring 128. In some embodiments, the plurality of clamps 210 are configured to hold the first heater 121 disposed atop the dielectric lid plate 120.

In some embodiments, the lid assembly 190 includes one or more gas conduits 202 extending from the lid ring 128 to the one or more gas inlets 126. The one or more gas inlets 126 may be disposed in a gas inlet tube 242 that is configured for delivering process gases from the gas panel 138 to the interior volume 105. For example, as shown in FIG. 2, four gas conduits extend to four gas inlets. In some embodiments, the one or more gas conduits 202 may be coupled to the lid ring 128 via mounting brackets 244. In some embodiments, an insulator block 252 may be coupled to the first heater 121 corresponding to the locations of the one or more gas conduits 202. The insulator block 252 includes a passageway 254 to allow for one of the one or more gas conduits 202 to pass through and is configured to shield the gas conduit from heat from the first heater 121. In some embodiments, each insulator block 252 is aligned with one of the mounting brackets 244. An upper surface of the lid ring 128 may include an o-ring groove 215 to provide a seal between the lid assembly 190 and the plasma source 102.

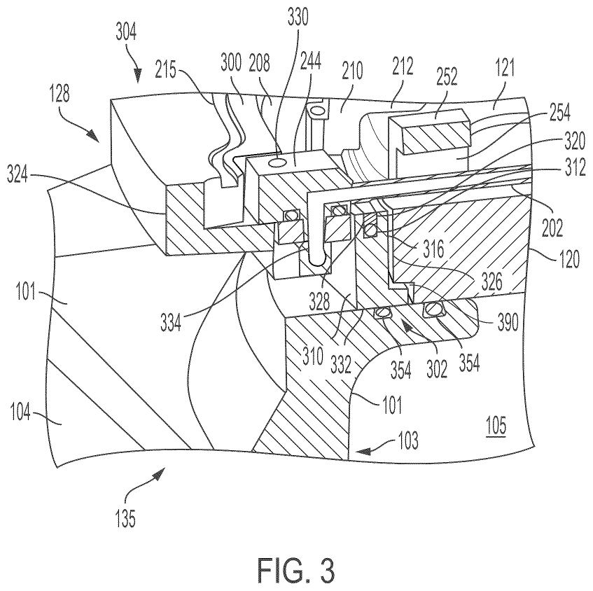

FIG. 3 depicts a cross-sectional view of an upper portion 135 of a process chamber in accordance with at least some embodiments of the present disclosure. The lid ring 128 includes a body 300 having an inner end 302 and an outer end 304. The lid ring 128 includes a first heater ring 310 at the inner end 302 that is disposed about the dielectric lid plate 120. In some embodiments, the first heater ring 310 is disposed radially between the dielectric lid plate 120 and the outer end of the lid ring 128. In some embodiments, the outer end 304 includes the o-ring groove 215 disposed on an upper surface thereof. In some embodiments, the o-ring groove 215 bends around the mounting brackets 244. The mounting brackets 244 may be coupled to the body 300 via a fastener opening 330. Each of the mounting brackets 244 include a gas channel 334 coupled to and aligned with one of the one or more gas conduits 202.

The first heater ring 310 includes a second heater 312 comprising one or more resistive heating elements that emit heat when coupled to a power source. The second heater 312 may be at least one of embedded in, coupled to, or printed on the first heater ring 310. In some embodiments, the first heater ring 310 includes an annular recess 320 extending from an upper surface of the first heater ring 310. In some embodiments, the second heater 312 is disposed in the annular recess 320. In some embodiments, a cover plate 328 is disposed in the annular recess 320 to enclose the second heater 312.

The first heater ring 310 is advantageously spaced from the dielectric lid plate 120 and not in direct contact with the dielectric lid plate 120 to reduce or prevent thermal crosstalk therebetween. For example, a radially inner surface 316 of the first heater ring 310 is spaced from an opposing radially outer surface 326 of the dielectric lid plate 120 to form a gap 390 therebetween. In some embodiments, the gap 390 is non-linear. In some embodiments, the gap 390 has a substantially uniform width.

In some embodiments, the first heater ring 310 has an L-shaped cross-sectional profile. For example, in some embodiments, a radially innermost surface (i.e., radially innermost surface of radially inner surface 316) of the first heater ring 310 is disposed radially inward of an outermost surface (i.e., radially outermost surface of radially outer surface 326) of the dielectric lid plate 120. In some embodiments, the plurality of clamps 210 are coupled to an upper surface of the first heater ring 310. In some embodiments, a lower surface 324 of the outer end 304 is raised with respect to a lower surface 332 of the inner end 302.

The first heater ring 310 is in physical contact with the upper liner 101 and configured to directly heat the upper liner 101 and to heat the chamber body 104 via the upper liner 101. In some embodiments, an RF gasket 354 is disposed between the first heater ring 310 and the upper liner 101. In some embodiments, an o-ring 358 is disposed between the upper liner 101 and the dielectric lid plate 120 radially inward of the RF gasket 354. In some embodiments, the first heater ring 310 is advantageously disposed radially inward of the tubular body 103.

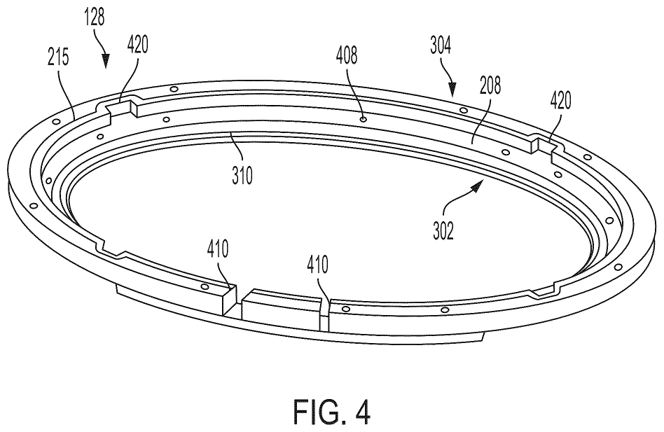

FIG. 4 depicts an isometric view of a lid ring 128 in accordance with at least some embodiments of the present disclosure. In some embodiments, the upper surface 208 of the lid ring 128 includes openings 408 for the plurality of clamps 210. For example, the openings 408 may be configured to receive a fastener, a pin, or the like. In some embodiments, the lid ring 128 includes a plurality of cutouts 420 sized to receive the mounting brackets 244. In some embodiments, the plurality of cutouts 420 are adjacent to the upper surface 208. In some embodiments, the outer end 304 of the lid ring 128 includes one or more slots 410 for power cables, wires, or the like.

FIG. 5 depicts a cross-sectional view of a lower portion 145 of the process chamber 100 in accordance with at least some embodiments of the present disclosure. In some embodiments, a second heater ring 170 is disposed between the flow valve body 160 and the chamber body 104. The second heater ring 170 includes a third heater 510 at least one of coupled to, printed on, or disposed therein comprising one or more resistive heating elements. The third heater 510 is configured to heat the flow valve body 160 and the chamber body 104 to further control a temperature profile thereof. In some embodiments, an o-ring 504 is disposed between the second heater ring 170 and the chamber body 104 to provide a seal therebetween. In some embodiments, a second o-ring 508 is disposed between the second heater ring 170 and the flow valve body 160 to provide a seal therebetween. In some embodiments, an RF gasket 512 is disposed between the second heater ring 170 and the flow valve body 160 to shield from electromagnetic radiation therebetween.

In some embodiments, the second heater ring 170 includes a second annular recess 530 extending from an upper surface 538 of the second heater ring 170. In some embodiments, the third heater 510 is disposed in the second annular recess 530. In some embodiments, a second cover plate 506 is disposed atop the second annular recess 530 to enclose the third heater 510. In some embodiments, the second cover plate 506 extends to an outer surface of the second heater ring 170. The inventors have observed that such an arrangement provides improved thermal coupling. In some embodiments, the first heater 121 advantageously controls a temperature of the interior volume 105 via the dielectric lid plate 120 while the second heater 312 and the third heater 510 advantageously control a temperature profile of the chamber body 104 and the flow valve body 160. As such, process uniformity is improved and unwanted deposition on surfaces of chamber components is reduced.

While the foregoing is directed to embodiments of the present disclosure, other and further embodiments of the disclosure may be devised without departing from the basic scope thereof.

1. A lid assembly for a process chamber, comprising:
a dielectric lid plate coupled to a first heater having one or more resistive heating elements disposed therein that are configured to heat the dielectric lid plate; and
a lid ring disposed about the dielectric lid plate and configured to hold the dielectric lid plate, wherein the lid ring includes a first heater ring disposed at an inner end of the lid ring and about the dielectric lid plate that includes a second heater comprising one or more resistive heating elements and wherein a radially inner surface of the first heater ring is spaced from an opposing radially outer surface of the dielectric lid plate so that the first heater ring is not in direct contact with the dielectric lid plate.

2. The lid assembly of claim 1, wherein the first heater ring includes an annular recess extending from an upper surface of the first heater ring, the second heater is disposed in the annular recess, and a cover plate disposed in the annular recess to enclose the second heater.

3. The lid assembly of claim 1, wherein the first heater ring has an L-shaped cross-sectional profile.

4. The lid assembly of claim 1, wherein the first heater ring is disposed radially between the dielectric lid plate and an outer end of the lid ring.

5. The lid assembly of claim 1, wherein a radially innermost surface of the first heater ring is disposed radially inward of an outermost surface of the dielectric lid plate.

6. The lid assembly of claim 1, wherein the first heater comprises an annular body and a plurality of fingers extending radially inward from the annular body.

7. The lid assembly of claim 1, further comprising a plurality of clamps coupled to an upper surface of the first heater ring at regular intervals.

8. A process chamber, comprising:
a chamber body having an interior volume therein defined by sidewalls and a lid assembly disposed atop the sidewalls;
an upper liner disposed in the interior volume; and
wherein the lid assembly comprises:
a dielectric lid plate coupled to a first heater having one or more resistive heating elements disposed therein that are configured to heat the dielectric lid plate; and
a lid ring disposed about the dielectric lid plate and configured to hold the dielectric lid plate, wherein the lid ring includes a first heater ring disposed at an inner end of the lid ring and about the dielectric lid plate that includes a second heater comprising one or more resistive heating elements, wherein the first heater ring is spaced from the dielectric lid plate and not in direct contact with the dielectric lid plate, and wherein the first heater ring is in physical contact with the upper liner;
a flow valve body coupled to a lower end of the chamber body; and
a second heater ring disposed between the flow valve body and the chamber body and having a third heater comprising one or more resistive heating elements disposed therein and configured to heat the flow valve body.

9. The process chamber of claim 8, further comprising an RF gasket disposed between the first heater ring and the upper liner.

10. The process chamber of claim 9, further comprising an o-ring disposed between the upper liner and the dielectric lid plate, wherein the o-ring is disposed radially inward of the RF gasket.

11. The process chamber of claim 8, wherein the second heater ring includes an annular recess extending from an upper surface of the second heater ring, and wherein the third heater is disposed in the second heater ring.

12. The process chamber of claim 8, wherein the upper liner has no heater channels or coolant channels disposed therein.

13. The process chamber of claim 8, wherein the first heater comprises an annular body and a plurality of fingers extending radially inward from the annular body.

14. The process chamber of claim 8, further comprising a plurality of clamps coupled to the first heater ring, wherein the plurality of clamps are configured to hold the first heater.

15. The process chamber of claim 8, further comprising an RF gasket disposed between the second heater ring and the flow valve body.

16. A process chamber, comprising:
a chamber body having an interior volume therein defined by sidewalls and a lid assembly disposed atop the sidewalls;
an upper liner disposed in the interior volume;
wherein the lid assembly comprises:
a lid assembly disposed atop the chamber body, wherein the lid assembly comprises:
a dielectric lid plate coupled to a first heater having one or more resistive heating elements disposed therein that are configured to heat the dielectric lid plate; and
a lid ring disposed about the dielectric lid plate and configured to clamp the dielectric lid plate against the upper liner, wherein the lid ring includes a first heater ring disposed at an inner end of the lid ring and about the dielectric lid plate that includes a second heater comprising one or more resistive heating elements, wherein the first heater ring is spaced from the dielectric lid plate and not in direct contact with the dielectric lid plate, and wherein the first heater ring is in physical contact with the upper liner;
a flow valve body coupled to a lower end of the chamber body;
a second heater ring disposed between the flow valve body and the chamber body and having a third heater disposed therein comprising one or more resistive heating elements disposed therein and configured to heat the flow valve body; and
a plasma source coupled to a top of the lid assembly.

17. The process chamber of claim 16, further comprising a turbopump coupled to the flow valve body and disposed vertically below the flow valve body.

18. The process chamber of claim 16, wherein the flow valve body is disposed vertically below the chamber body.

19. The process chamber of claim 16, wherein the flow valve body includes a port opening on a bottom plate of the flow valve body, and further comprising a poppet disposed in the flow valve body configured to selectively open or close the port opening.

20. The process chamber of claim 16, further comprising an o-ring disposed between the second heater ring and the chamber body, and a second o-ring disposed between the second heater ring and the flow valve body.
